(19) United States
(12) Patent Application Publication
(10) Pub. No.: US 2021/0185800 A1
(43) Pub. Date: Jun. 17, 2021

(54) CIRCUIT BOARD

(71) Applicant: CHIPBOND TECHNOLOGY CORPORATION, Hsinchu (TW)

(72) Inventors: Yi-Chen Lien, Taichung City (TW); Yen-Ping Huang, Kaohsiung City (TW); Hui-Yu Huang, Hsinchu City (TW); Chih-Ming Peng, Taichung City (TW); Chun-Te Lee, Hsinchu County (TW)

(21) Appl. No.: 16/866,796

(22) Filed: May 5, 2020

(30) Foreign Application Priority Data
Dec. 16, 2019 (TW) 108145959

(51) Int. Cl. H05K 1/02; H05K 3/00

(52) U.S. Cl. CPC H05K 1/0266; H05K 2201/09063; H05K 2203/162; H05K 3/005

(57) ABSTRACT

A circuit board includes a substrate having a through hole, a circuit layer, a first measurement mark and a second measurement mark. According to the first and second measurement marks, an electronic detection device can measure a first distance between a first edge of the through hole and the first measurement mark and a second distance between a second edge of the through hole and the second measurement mark to determine whether the through hole has an undesired size or shift.

### FIELD OF THE INVENTION

This invention relates to a circuit board, and more particularly to a circuit board having a through hole for exposing an electronic component such as fingerprint reader.

### BACKGROUND OF THE INVENTION

According to product demand, a conventional circuit board may be punched to form a through hole. However, the through hole may shift or have an undesired size due to blunt punch cutter, tilted/bended circuit board or misalignment between punch cutter and circuit board.

As shown in FIG. 1, conventionally, a standard sample 10 having an inspection hole 11 is used to check the through hole. The standard sample 10 is placed on the circuit board to confirm whether the through hole on the circuit board is within the inspection hole 11 so as to determine whether the through hole conforms to standards or not.

Overlapping the standard sample 10 with the circuit board is necessary for checking the through hole, but personal error, such as alignment error or collimation error, may be occurred to cause false determination. Further, the use of the standard sample 10 may also reduce production efficiency.

### SUMMARY

One object of the present invention is to provide two measurement marks on both sides of a through hole, respectively, to help an electronic detection device to measure the through hole for preventing false determination and increasing production efficiency.

A circuit board of the present invention includes a substrate having a through hole, a circuit layer, a first measurement mark and a second measurement mark. The through hole penetrates through the substrate and is provided for exposing an electronic component. The circuit layer is disposed on a surface of the substrate. The first measurement mark includes a first measurement position which is located outside a first edge of the through hole, and a shortest distance between the first measurement position and the first edge along a first direction is defined as a first distance. The second measurement mark includes a second measurement position which is located outside a second edge of the through hole, and a shortest distance between the second measurement position and the second edge along a second direction is defined as a second distance. The second direction is intersected with the first direction.

According to the first and second measurement marks located outside the first and second edges of the through hole, an electronic detection device can measure the first distance between the first measurement position and the first edge and the second distance between the second measurement position and the second edge to determine whether the through hole is shifted or has a undesired size so as to avoid false determination and increase production efficiency.

### DESCRIPTION OF THE DRAWINGS

FIG. 1 is a schematic diagram illustrating a conventional standard sample.

FIG. 2 is a top view diagram illustrating a circuit board in accordance with a first embodiment of the present invention before forming a through hole.

FIG. 3 is a partial enlarged diagram of FIG. 2.

FIG. 4 is a top view diagram illustrating the circuit board in accordance with the first embodiment of the present invention after forming a through hole.

FIG. 5 is a partial enlarged diagram of FIG. 4.

FIG. 6 is a top view diagram illustrating a circuit board in accordance with a second embodiment of the present invention before forming a through hole.

FIG. 7 is a partial enlarged diagram of FIG. 6.

FIG. 8 is a top view diagram illustrating the circuit board in accordance with the second embodiment of the present invention after forming a through hole.

FIG. 9 is a partial enlarged diagram of FIG. 8.

FIG. 10 is a top view diagram illustrating a circuit board in accordance with a third embodiment of the present invention before forming a through hole.

FIG. 11 is a partial enlarged diagram of FIG. 10.

FIG. 12 is a top view diagram illustrating the circuit board in accordance with the third embodiment of the present invention after forming a through hole.

FIG. 13 is a partial enlarged diagram of FIG. 12.

FIG. 14 is a top view diagram illustrating a circuit board in accordance with a fourth embodiment of the present invention before forming a through hole.

FIG. 15 is a partial enlarged diagram of FIG. 14.

FIG. 16 is a top view diagram illustrating the circuit board in accordance with the fourth embodiment of the present invention after forming a through hole.

FIG. 17 is a partial enlarged diagram of FIG. 16.

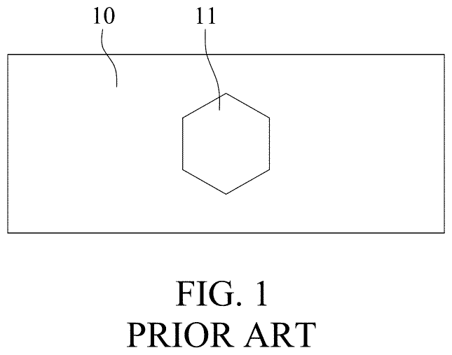

### DETAILED DESCRIPTION OF THE INVENTION

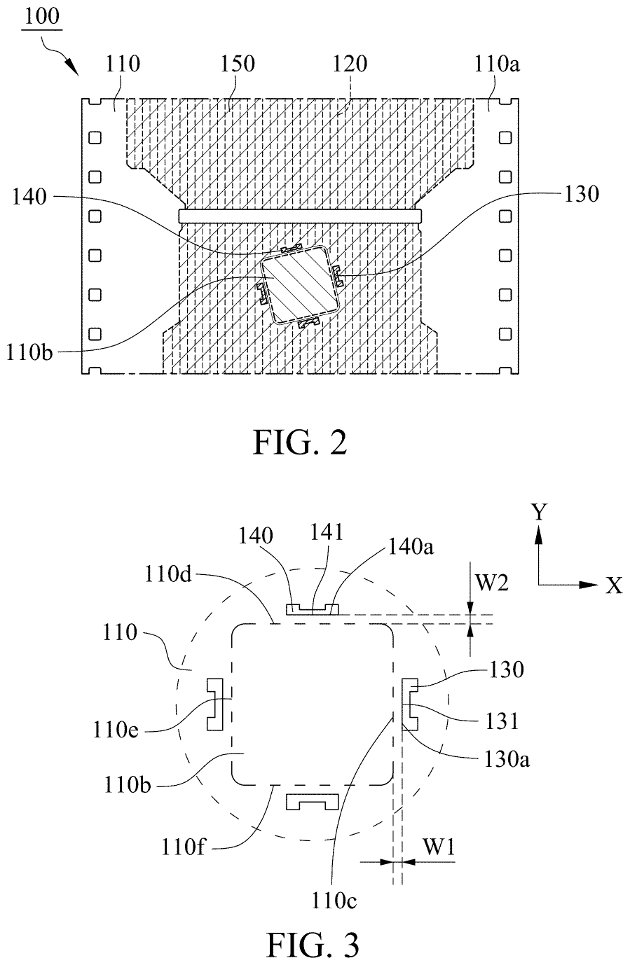

With reference to FIGS. 2 to 5, a circuit board 100 in accordance with a first embodiment of the present invention includes a substrate 110, a circuit layer 120, a first measurement mark 130 and a second measurement mark 140, and preferably, the circuit board 100 further includes a protective insulation layer 150. The substrate 110 is, but not limited to, made of polyimide (PI), the circuit layer 120 is located on a surface 110a of the substrate 110 and includes a plurality of circuit lines, the protective insulation layer 150 covers the circuit layer 120. A through hole forming region 110b is defined on the surface 110a, and a punch tool (not shown) is provided to punch the through hole forming region 110b to form a through hole 111 on the substrate 110. The through hole 111 penetrates through the substrate 110 for revealing an electronic component such as fingerprint reader (not shown).

With reference to FIGS. 2 and 3, the though hole forming region 110b at least has a first predetermined edge 110c and a second predetermined edge 110d, and in the first embodiment, the through hole forming region 110b is a rectangular region and further has a third predetermined edge 110e and a fourth predetermined edge 110f. The third predetermined edge 110e is opposite to the first predetermined edge 110c, the fourth predetermined edge 110f is opposite to the second predetermined edge 110d. The first and second predetermined edges 110c/110d are adjacent and connected to each other, the second and third predetermined edges 110d/110e are adjacent and connected to each other, the third and fourth predetermined edges 110e/110f are adjacent and connected to each other, and the fourth and first predetermined edges 110f/110c are adjacent and connected to each other.

With reference to FIGS. 2 and 3, the first and second measurement marks 130/140 are located on the same surface (the surface 110a) of the substrate 110 in the first embodiment, and they may located on different surfaces of the substrate 110, respectively, in other embodiments.

With reference to FIGS. 2 and 3, the circuit layer 120, the first measurement mark 130 and the second measurement mark 140 may formed on the surface 110a of the substrate 110 by casting, lamination, sputtering or plating.

With reference to FIGS. 2 and 3, the circuit layer 120 and one or both of the first and second measurement marks 130/140 are made of a same material. The protective insulation layer 150 may cover one or both of the first and second measurement marks 130/140, expose (not cover) one or both of the first and second measurement marks 130/140 or expose (not cover) both of the first and second measurement marks 130/140. One or both of the first and second measurement marks 130/140 may be not electrically connected to the circuit layer 120. In the first embodiment, both of the first and second measurement marks 130/140 are made of a metal material and not electrically connected to the circuit layer 120. In other embodiments, however, one or both of the first and second measurement marks 130/140 are electrically connected to the circuit layer 120.

With reference to FIGS. 2 and 3, the protective insulation layer 150 and one or both of the first and second measurement marks 130/140 may be made of an insulation material in other embodiments such that the protective insulation layer 150 and one or both of the first and second measurement marks 130/140 are formed at the same time. Preferably, all of the protective insulation layer 150, the first measurement mark 130 and the second measurement mark 140 are formed simultaneously.

With reference to FIGS. 2 and 3, in the first embodiment, the first measurement mark 130 is located outside the first predetermined edge 110c of the through hole forming region 110b, and the second measurement mark 140 is located outside the second predetermined edge 110d of the through hole forming region 110b. The shapes of the first and second measurement marks 130/140 are not limited in the present invention, they can be any shape. The first measurement mark 130 includes at least one first measurement position 131 which is located at a first measurement edge 130a of the first measurement mark 130, and the second measurement mark 140 includes at least one second measurement position 141 which is located at a second measurement edge 140a of the second measurement mark 140. Preferably, the first measurement edge 130a and the first predetermined edge 110c are parallel, and the second measurement edge 140a and the second predetermined edge 110d are parallel.

With reference to FIG. 3, a shortest distance between the first measurement position 131 and the first predetermined edge 110c along a first direction X is defined as a first predetermined distance W1. And along a second direction Y intersected with the first direction X, a shortest distance between the second measurement position 141 and the second predetermined edge 110d is defined as a second predetermined distance W2. In the first embodiment, the first and second directions X/Y are perpendicular to one another.

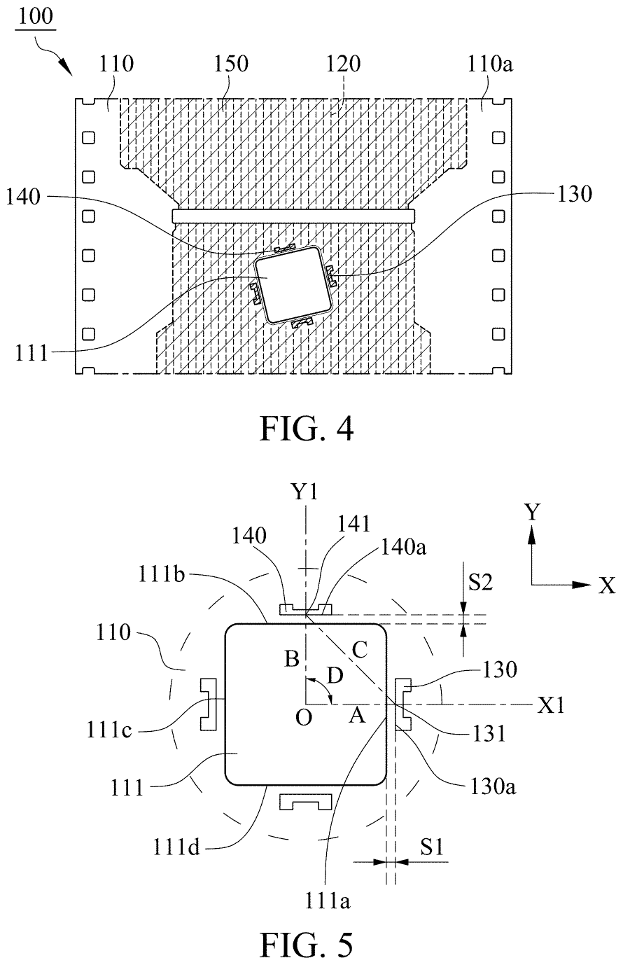

With reference to FIGS. 4 and 5, the through hole forming region 110b is preferably punched by using the punch tool (not shown) to form the through hole 111. The through hole 111 on the substrate 110 has a first edge 111a and a second edge 111b, and in the first embodiment, the through hole 111 is a rectangular hole further having a third edge 111c and a fourth edge 111d. The first and second edges 111a/111b are adjacent and connected with one another, the second and third edges 111b/111c are adjacent and connected with one another, the third and fourth edges 111c/111d are adjacent and connected with one another, and the fourth and first edges 111d/111a are adjacent and connected with one another.

With reference to FIGS. 4 and 5, the first and second measurement marks 130/140 are located outside the through hole 111, particularly, the first measurement mark 130 is located outside the first edge 111a of the through hole 111, and the second measurement mark 140 is located outside the second edge 111b of the through hole 111. And one or both of the first and second measurement marks 130/140 are located between the circuit layer 120 and the through hole 111. The first measurement edge 130a of the first measurement mark 130 is preferably parallel to the first edge 111a of the through hole 111, and the second measurement edge 140a of the second measurement mark 140 is parallel to the second edge 111b of the through hole 111.

With reference to FIG. 5, the relative positions of the first measurement position 131 of the first measurement mark 130, the second measurement position 141 of the second measurement mark 140 and the through hole 111 are defined by a first axis X1 and a second axis Y. In the first embodiment, the first axis X1 extends along the first direction X and the second axis Y1 extends along the second direction Y.

With reference to FIG. 5, the first axis X passes through the first measurement position 131 and extends toward the through hole 111, the second axis Y1 passes through the second measurement position 141 and extends toward the through hole 111. The first and second axes X1/Y1 are intersected at an intersection point O and an included angle D exists between them. The values of a first linear distance A between the intersection point O and the first measurement position 131, a second linear distance B between the intersection point O and the second measurement position 141, a third linear distance C between the first and second measurement positions 131/141 and the included angle D satisfy the formula presented as follows:

C²=A²+B²−2AB cos D

With reference to FIG. 5, a shortest distance between the first measurement position 131 and the first edge 111a along the first direction X is defined as a first distance S1, and a shortest distance between the second measurement position 141 and the second edge 111b along the second direction Y is defined as a second distance S2.

With reference to FIGS. 3 and 5, the absolute difference between the first predetermined distance W1 and the first distance S1 is equal to or lower than 0.3 mm (|W1−S1|≤0.3 mm), and the absolute difference between the second predetermined distance W2 and the second distance S2 is also equal to or lower than 0.3 mm (|W2−S2|≤0.3 mm).

After forming the through hole 111 by the punch tool, an electronic detection device is provided to measure the first distance S1 between first measurement position 131 and the first edge 111a and measure the second distance S2 between the second measurement position 141 and the second edge 111b. According to the measured values of the first and second distances S1/S2, the electronic detection device can determine whether the through hole 111 has an undesired diameter or shift. And if the through hole 111 is shifted, the electronic detection device is also provided to determine whether the shifted through hole 111 conforms to standards so as to prevent the false determination due to personal error and enhance manufacturing efficiency of the circuit board 100.

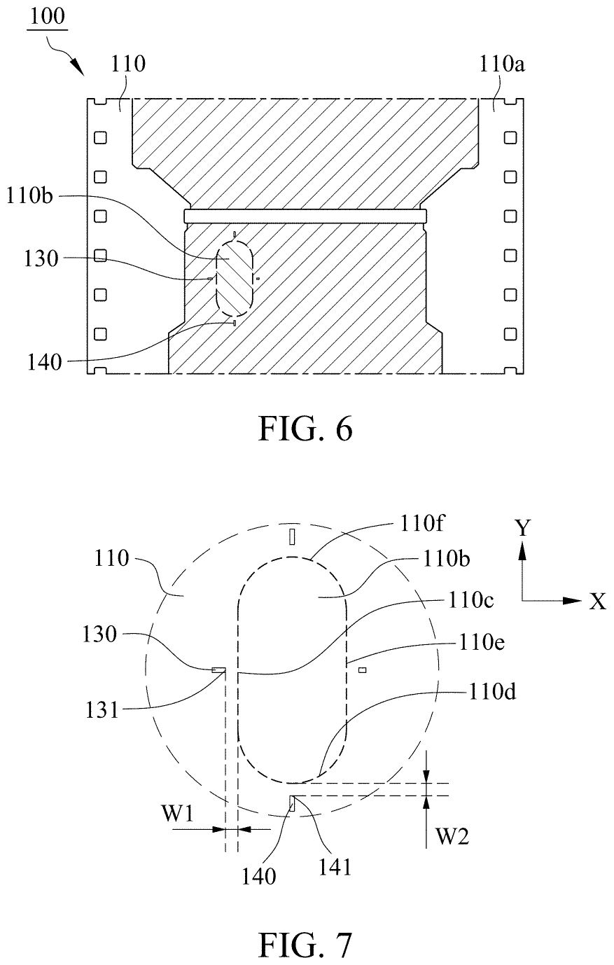

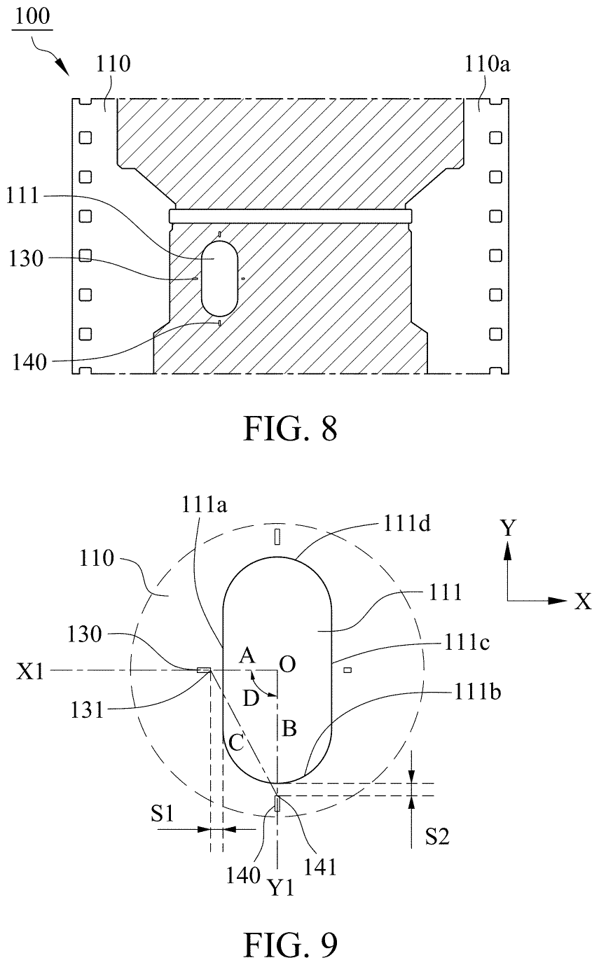

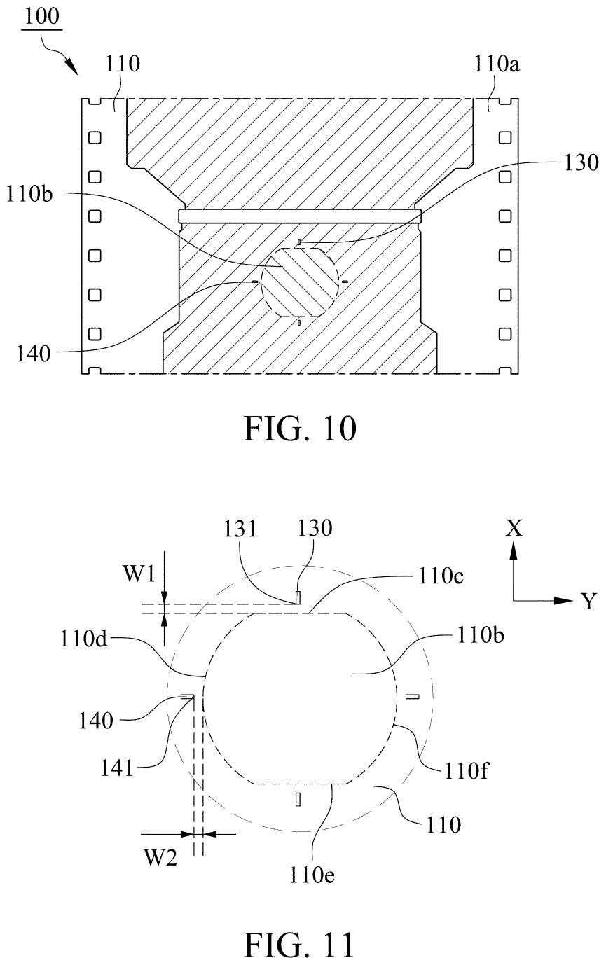

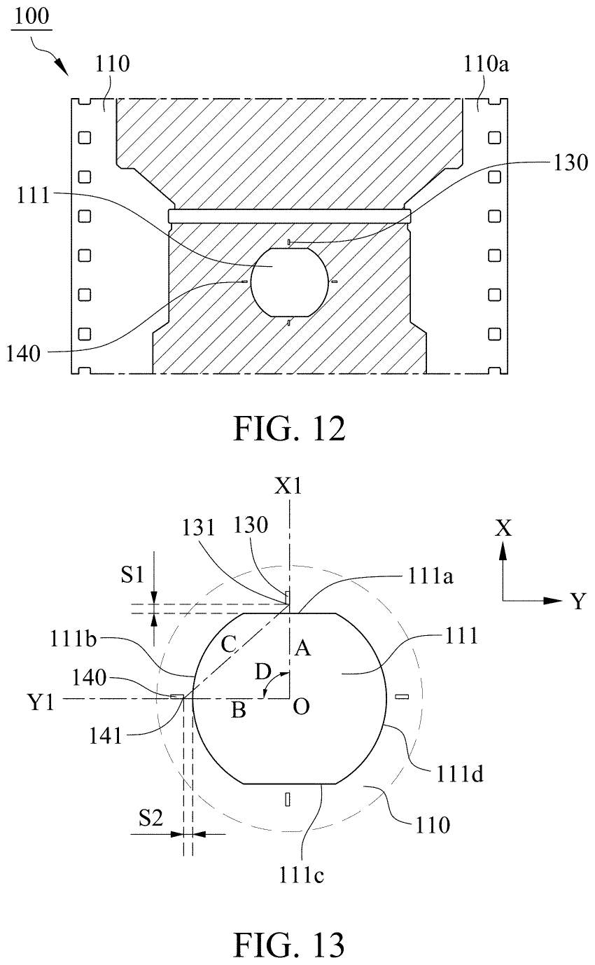

FIGS. 6 to 9 and FIGS. 10 to 13 show a second embodiment and a third embodiment of the present invention, respectively. In the second and third embodiments, the second predetermined edge 110d and the fourth predetermined edge 110f of the through hole forming region 110b are circle arc, different to the first embodiment. And the second edge 111b and the fourth edge 111d of the through hole 111 formed by the punch tool are arc edges, preferably, the second axis Y1 passes through centers of the second edge 111b and the fourth edge 11l d.

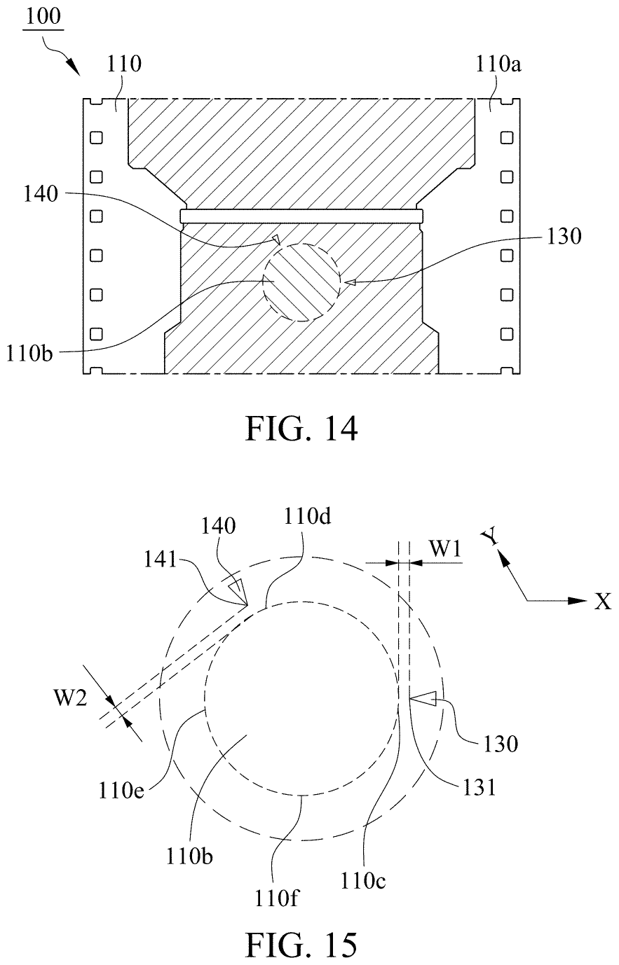

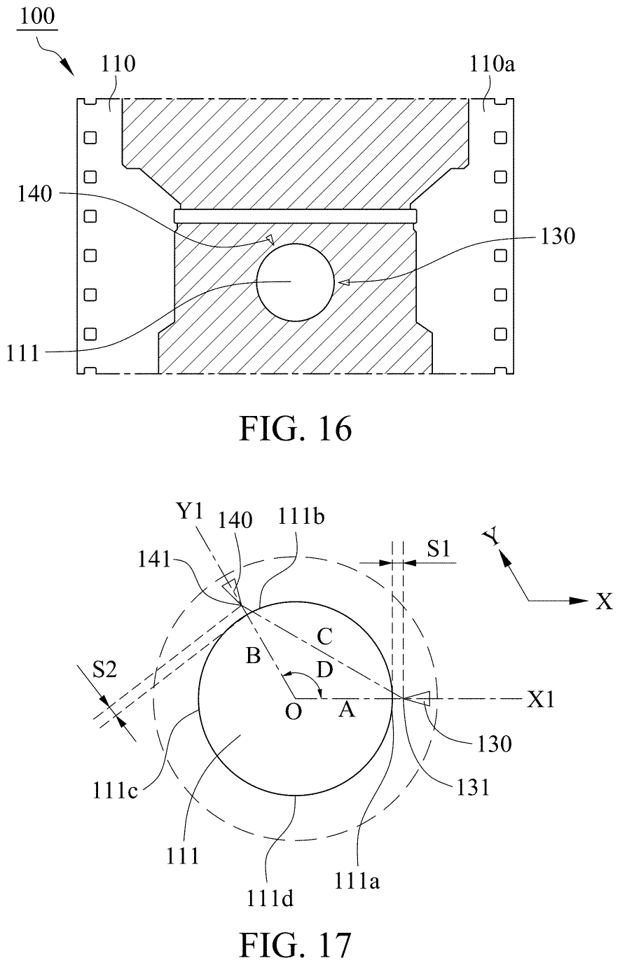

A fourth embodiment of the present invention is represented in FIGS. 14 to 17. Different to the first embodiment, the first to fourth predetermined edges 110c/110d/110e/110f of the through hole forming region 110b are arc edges, and the through hole forming region 110b is circular in the fourth embodiment. After punching, the first to fourth edges 11a/111b/111c/111d of the through hole 111 are also arc edges and the through hole 111 is a circular hole. In the fourth embodiment, the first axis X1 passes through the first measurement position 131, the second axis Y1 passes through the second measurement position 141, and the first axis X1 is not perpendicular to the second axis Y1.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A circuit board comprising:
a substrate having a through hole penetrating through the substrate and configured to expose an electronic component;
a circuit layer disposed on a surface of the substrate;
a first measurement mark including a first measurement position located outside a first edge of the through hole, wherein a shortest distance between the first measurement position and the first edge along a first direction is defined as a first distance; and
a second measurement mark including a second measurement position located outside a second edge of the through hole, wherein a shortest distance between the second measurement position and the second edge along a second direction intersecting with the first direction is defined as a second distance and wherein the first and second measurement marks are configured for measuring the through hole.

2. The circuit board in accordance with claim 1, wherein the first and second measurement marks are disposed on the surface.

3. (canceled)

4. The circuit board in accordance with claim 1, wherein the first measurement position is located at a first measurement edge of the first measurement mark.

5. The circuit board in accordance with claim 4, wherein the first measurement edge and the first edge of the through hole are parallel.

6. The circuit board in accordance with claim 4, wherein the second measurement position is located at a second measurement edge of the second measurement mark.

7. The circuit board in accordance with claim 5, wherein the second measurement position is located at a second measurement edge of the second measurement mark.

8. The circuit board in accordance with claim 6, wherein the second measurement edge and the second edge of the through hole are parallel.

9. The circuit board in accordance with claim 7, wherein the second measurement edge and the second edge of the through hole are parallel.

10. (canceled)

11. (canceled)

12. The circuit board in accordance with claim 1 further comprising a protective insulation layer, wherein the protective insulation layer covers the circuit layer and covers one or both of the first and second measurement marks.

13. The circuit board in accordance with claim 1 further comprising a protective insulation layer, wherein the protective insulation layer covers the circuit layer and exposes one or both of the first and second measurement marks.

14. The circuit board in accordance with claim 1, wherein one or both of the first and second measurement marks are located between the circuit layer and the through hole.

15. The circuit board in accordance with claim 1, wherein the circuit layer and one or both of the first and second measurement marks are made of a same material.

16. The circuit board in accordance with claim 1, wherein one or both of the first and second measurement marks are made of an insulation material.

17. The circuit board in accordance with claim 16 further comprising a protective insulation layer, wherein the protective insulation layer covers the circuit layer and is made of the insulation material.

18. The circuit board in accordance with claim 1, wherein a first axis passes through the first measurement position and extends toward the through hole, a second axis passes through the second measurement position and extends toward the through hole, the first and second axes are intersected at an intersection point and an included angle exists between the first and second axes, and wherein values of a first linear distance between the intersection point and the first measurement position, a second linear distance between the intersection point and the second measurement position, a third linear distance between the first and second measurement positions and the included angle satisfy a formula presented as follows:
C²=A²+B²−2AB cos D
wherein A is the value of the first linear distance, B is the value of the second linear distance, C is the value of the third linear distance, and D is the value of the included angle.

19. The circuit board in accordance with claim 1, wherein a through hole forming region is defined on the surface of the substrate and the through hole is formed within the through hole forming region, a shortest distance between the first measurement position and a first predetermined edge of the through hole forming region along the first direction is defined as a first predetermined distance, and a shortest distance between the second measurement position and a second predetermined edge of the through hole forming region along the second direction is defined as a second predetermined distance, and wherein an absolute difference between the first predetermined distance and the first distance is equal to or lower than 0.3 mm and an absolute difference between the second predetermined distance and the second distance is equal to or lower than 0.3 mm.
